(19) United States
(12) Patent Application Publication
(10) Pub. No.: US 2017/0221983 A1
(43) Pub. Date: Aug. 3, 2017

(54) IN-SITU DOPED THEN UNDOPED POLYSILICON FILLER FOR TRENCHES

(71) Applicant: Texas Instruments Incorporated, Dallas, TX (US)

(72) Inventors: BHASKAR SRINIVASAN, ALLEN, TX (US); BINGHUA HU, PLANO, TX (US); KHANH QUANG LE, GARLAND, TX (US); SOPA CHEVACHAROENKUL, RICHARDSON, TX (US)

(21) Appl. No.: 15/009,059

(22) Filed: Jan. 28, 2016

(51) Int. Cl. H01L 49/02

(52) U.S. Cl. CPC H01L 28/20

(57) ABSTRACT

A method of fabricating an integrated circuit (IC) includes etching a trench in a semiconductor layer on a substrate having an aspect ratio (AR)≧5 and a trench depth≧10 μm. A dielectric liner is formed along the walls of the trench. An in-situ doped polysilicon layer having a first thickness is deposited into the trench to form a dielectric lined partially filled trench. An un-doped polysilicon layer having a second thickness greater than the first thickness is deposited on the in-situ doped polysilicon layer to complete a filling of the trench to provide a polysilicon filled trench. The doped polysilicon filler after completion of fabricating the IC is essentially polysilicon void-free and has a 25° C. sheet resistance≦60 ohms/sq. The method can include etching an opening at a bottom of the dielectric liner before depositing the polysilicon to provide ohmic contact to the semiconductor layer.

### CROSS-REFERENCE TO COPENDING APPLICATIONS

This application has subject matter related to copending application Ser. No. 14/570,530 entitled “IN-SITU DOPED POLYSILICON FILLER FOR TRENCHES” that was filed on Dec. 15, 2014.

### FIELD

Disclosed embodiments relate to doped polysilicon filled trenches for integrated circuits (ICs).

### BACKGROUND

Active devices on a chip are generally spaced apart by regions known as field regions in which the isolation structures are formed. An alternative to the LOCal Oxidation of Silicon (LOCOS) process for isolation is known as trench isolation. Some trench processes involve doped polysilicon fillers, such as when an ohmic contact is needed to be made between the polysilicon filler and the semiconductor substrate.

In one trench arrangement having doped polysilicon fillers, a two-step implant polysilicon filling process is used. A trench is formed in the substrate, such as by reactive ion etching (RIE), the trench is lined by a dielectric liner (e.g., thermal silicon oxide), and the lined trench is then filled by a polysilicon filler. The polysilicon filler material can then be doped, generally by ion implantation followed by a thermal implant activation step.

### SUMMARY

This Summary is provided to introduce a brief selection of disclosed concepts in a simplified form that are further described below in the Detailed Description including the drawings provided. This Summary is not intended to limit the claimed subject matter's scope.

Disclosed embodiments recognize conventional two-step deposition then ion implant to provide a doped polysilicon filler for trenches results in polysilicon voids that can migrate within the trench during annealing causing reliability issues and higher substrate contact resistance for circuit arrangements where the trench includes a bottom aperture through the dielectric liner so that the doped polysilicon contacts the semiconductor substrate (or epi layer thereon). Moreover, since the polysilicon filler is conventionally deposited undoped, an extra implant step is needed for dopant incorporation.

Disclosed embodiments describe methods for polysilicon trench fill including forming an initial in-situ doped polysilicon layer then an undoped polysilicon layer to form dielectric lined polysilicon filled trenches (polysilicon filled trenches). The doped polysilicon filler in the final integrated circuit (IC) after wafer fabrication completed is generally essentially polysilicon void-free. As used herein the term “polysilicon void” refers to an empty or cavity region within the polysilicon filler of a dielectric lined polysilicon filled trench that can be along the dielectric liner or within the polysilicon filler that has at least one dimension which is at least 0.3 μm long, typically being a v-shaped void (see voids shown in FIG. 3A described below). The term “essentially void-free” as used herein refers at least 90% of the plurality of dielectric lined polysilicon filled trenches on an IC being void-free throughout their volume determinable from cross-sectional scanning electron microscopy (X-SEM), where the polysilicon filled trenches have a depth of ≧10 μm and an aspect ratio≧5.

### BRIEF DESCRIPTION OF THE DRAWINGS

Reference will now be made to the accompanying drawings, which are not necessarily drawn to scale, wherein:

FIG. 1 is a flow chart that shows steps in an example method of fabricating an integrated circuit (IC) including forming in-situ doped polysilicon layer then forming an un-doped polysilicon layer for forming polysilicon filled trenches, according to an example embodiment.

FIG. 2A is a schematic cross-sectional view of an example IC including disclosed polysilicon filled trenches, according to an example embodiment.

FIG. 2B is a schematic cross-sectional view of an example IC including disclosed polysilicon filled trenches having an opening at a bottom of the dielectric liner to provide an ohmic contact between the doped polysilicon filler in the trench and the semiconductor substrate, according to an example embodiment.

FIG. 3A is a scanned X-SEM image of conventional polysilicon filled trenches having visible v-shaped voids, where the trenches were doped after polysilicon deposition by a boron ion implantation process then a dopant activation step.

FIG. 3B is a scanned X-SEM image of a disclosed test structure having disclosed polysilicon filled trenches with varying trench opening/width that simulated product features with varying trench openings/widths that were formed using a disclosed in situ boron doped layer then an un-doped polysilicon layer deposition process, where the doped polysilicon filler can be seen to be essentially polysilicon void-free, according to an example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

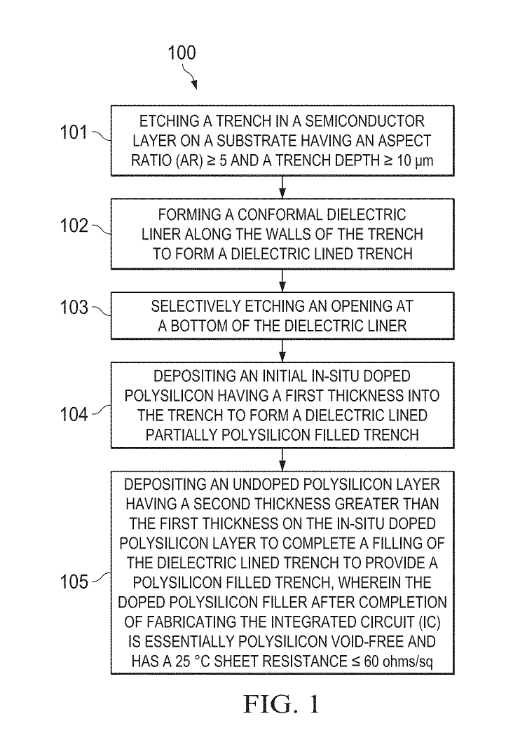

FIG. 1 is a flow chart that shows steps in an example method 100 of fabricating an IC including forming an in-situ doped polysilicon layer then forming polysilicon filled trenches, according to an example embodiment. Step 101 comprises etching a trench in a semiconductor substrate having an aspect ratio (AR)≧5 and a trench depth≧10 μm. The trench depth can be between 20 μm and 50 μm. In one particular embodiment, the trench opening dimension at the top semiconductor surface can be from 2.35 μm to 2.85 μm and the trench depth is about 25 μm to 30 μm.

The semiconductor substrate can be a bulk semiconductor substrate or can comprise an epitaxial layer on a bulk substrate material. The semiconductor substrate and/or semiconductor surface can comprise silicon, silicon-germanium, or other semiconductor material such as gallium arsenide (GaAs), indium phosphide (InP) or silicon carbide (SiC). One particular arrangement is a silicon/germanium (SiGe) semiconductor surface on a silicon substrate. The etching generally comprises reactive ion etching (RIE).

Step 102 comprises forming a conformal dielectric liner along the walls of the trench to provide a dielectric lined trench. The forming can comprise a thermal oxidation or a deposition process, or a combination of such processes. For example, in one particular embodiment the dielectric layer comprises silicon oxide formed using a thermal 2.5 kA silicon oxide layer process followed by a deposited sub-atmospheric CVD (SACVD) process to provide a silicon oxide layer about 5 kA thick.

For circuit arrangements where the trench needs a bottom aperture through the dielectric liner for the in-situ doped polysilicon to contact the semiconductor substrate or an epi layer on the substrate, such as to enable the trench to ohmically contact the substrate or epi layer from the topside (circuit side), method 100 can further comprise step 103 comprising selectively etching the dielectric liner to form an opening at a bottom of the dielectric liner before the in-situ doped polysilicon deposition (step 104 described below). This enables providing an ohmic contact between the later deposited doped polysilicon filler and the same doping type semiconductor substrate or epi layer. In one arrangement, the semiconductor substrate and/or epi layer thereon can be boron doped and the polysilicon can be boron doped. In another arrangement the semiconductor substrate and/or epi layer thereon can be n-typed doped and the polysilicon filler can be n-type doped.

Step 104 comprises depositing an initial in-situ doped polysilicon layer having a first thickness into the trench to form a dielectric lined partially polysilicon filled trench. A thickness of the in-situ doped polysilicon layer can be from 0.2 μm to 0.5 μm. Step 105 comprises depositing an un-doped polysilicon layer having a second thickness greater than the first thickness to complete a filling of the dielectric lined trench to provide a polysilicon filled trench. A thickness of the un-doped polysilicon layer can be from 1.3 μm to 2.0 μm.

After completion of fabricating the IC the polysilicon filled trench is essentially polysilicon void-free, and has a 25° C. sheet resistance less than or equal≦60 ohms/sq. Moreover, in the final IC the difference in dopant concentration from the top the polysilicon filled trench and the bottom of the polysilicon filled trench is at least a factor of 4, and an average polysilicon grain size at the top of the polysilicon filled trench is at least 50% less than an average grain size at the bottom of the polysilicon filled trench.

The doped polysilicon layer being capped by the undoped polysilicon layer helps avoid out-diffusion of dopant into the dielectric liner material (e.g., silicon oxide) along the sidewalls of the trench. As the polysilicon is generally deposited on both sides of the wafer, the capping layer may later be removed by Chemical Mechanical Planarization or Polishing (CMP) on the front surface of the wafer and by a backside polysilicon strip on the wafer backside.

The depositing in steps 104 and 105 can comprise Low Pressure Chemical Vapor Deposition (LPCVD) utilizing silane (SiH₄) gas at a deposition temperature range of 550° C. to 650° C. and a pressure range from 100 mTorr to 400 mTorr. The deposition temperature range is generally 555° C. to 625° C., and the pressure range is generally from 250 mTorr to 350 mTorr.

For the doped polysilicon deposition (step 104), the depositing can comprise flowing BCl₃ gas in a flow range from 20 to 50 sccm along with at least one diluent gas so that the source BCl₃ gas is diluted to ≦20% (e.g., 1% to 10%) by gravimetric volume. The diluent gas can comprise H₂. For example, it has been recognized that 100% BCl₃ generally results in attack of the dielectric liner material when it comprises silicon oxide. One specific deposition process uses 3% BCl₃ (balance 97% with H₂), and another process uses 5% BCl₃ (balance 95% H₂). The diluting gas can also be other gases besides H₂, such as N₂ or Ar.

The method 100 can further comprise annealing the polysilicon filled trenches at a temperature generally between 900° C. and 1150° C. For example, a furnace anneal at a temperature from 900° C. to 1100° C. for 10 to 65 minutes can be used, or a rapid thermal anneal (RTA) at a temperature between 900° C. to 1100° C. for about 30 to 60 seconds can be used. After the annealing of the polysilicon filled trenches through the completion of fabricating the IC the doped polysilicon filler is essentially polysilicon void-free.

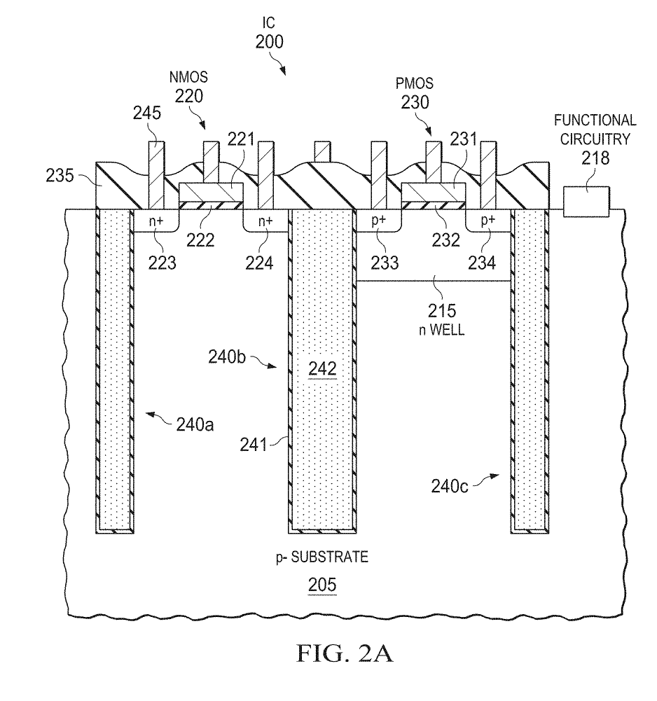

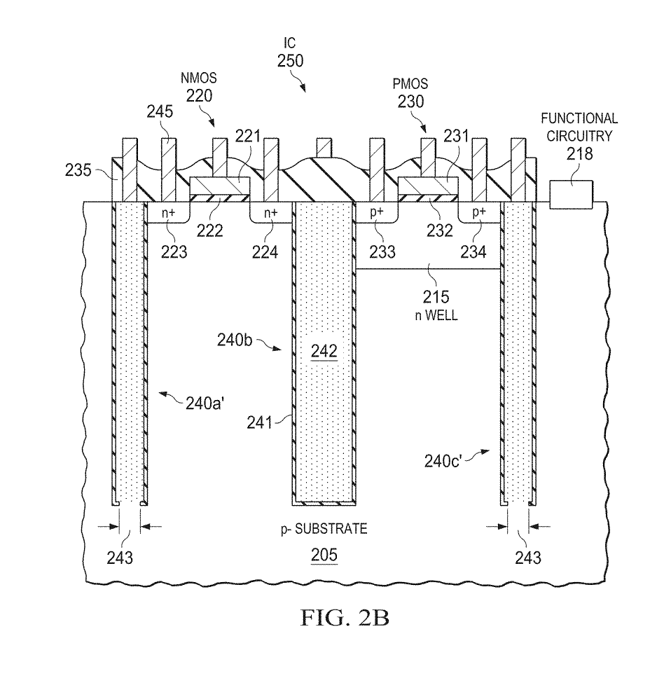

For the IC after completion of its fabrication process, the doped polysilicon filler generally has an average dopant concentration between 1×10¹⁸ cm⁻³ and 5×10²¹ cm⁻³, and a 25° C. sheet resistance of ≦60 ohms/sq. In a typical embodiment the polysilicon filler is doped p-type and the 25° C. sheet resistance is ≦30 oms/sq. In the embodiment there is a trench aperture at the bottom of the trench (see opening 243 at a bottom of the dielectric liner 241 for trenches 240a′ and 240c′ shown in FIG. 2B described below), the polysilicon filled trench forms an ohmic contact to the substrate or epi layer. The polysilicon filled trenches can be trench isolation structures on the IC, or other trench structures including trench capacitors, field plates, or rings.

FIG. 2A is a schematic cross-sectional view of an example CMOS IC 200 including disclosed polysilicon filled trenches 240a, 240b and 240c, according to an example embodiment. The IC 200 includes a semiconductor substrate 205 shown as a p- substrate having functional circuitry shown as functional circuitry block 218 formed on and in the semiconductor substrate 205. The functional circuitry 218 is generally integrated circuitry that realizes and carries out a desired functionality, such as that of a digital IC (e.g., digital signal processor) or analog IC (e.g., amplifier or a power converter), such as a BiMOS IC. The capability of the functional circuitry 218 provided may vary, for example ranging from a simple device to a complex device. The specific functionality contained within functional circuitry is not of importance to disclosed embodiments.

An NMOS transistor 220 and a PMOS transistor 230 are shown that are generally also included in the functional circuitry block 218 along with other CMOS circuitry, as well as with bipolar transistors for BiCMOS circuits, and resistors and capacitors configured together to perform a circuit function. The PMOS transistor 230 is shown formed in an nwell 215.

NMOS transistor 220 includes a gate electrode 221 on a gate dielectric 222 along with drain 223 and source 224 formed in the semiconductor substrate 205. PMOS transistor 230 includes a gate electrode 231 on a gate dielectric 232 along with source 233 and drain 234 formed in the semiconductor substrate 205. Contact metal 245 is shown providing contacts through apertures in the pre-metal dielectric layer 235 shown.

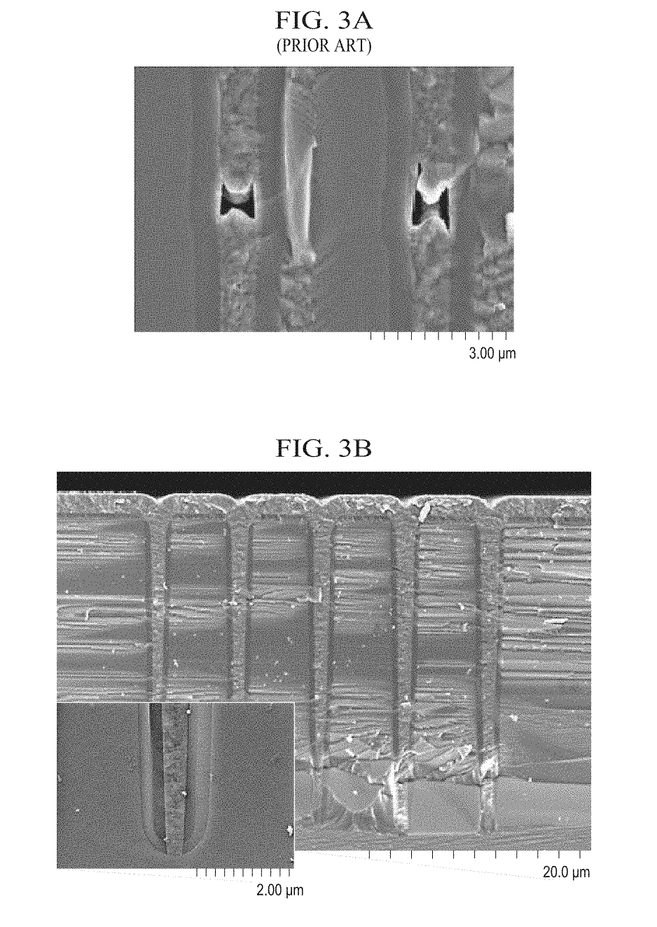

The polysilicon filled trenches 240a, 240b and 240c in the semiconductor substrate 205 provide electrical isolation, such as between the NMOS transistor 220 and PMOS transistor 230 shown. The dielectric liner is shown as 241 and the doped polysilicon filler as 242. The 25° C. sheet resistance of the doped polysilicon filler 242 is ≦60 ohms/sq, and AR of the plurality of polysilicon filled trenches 240 shown as 240a, 240b and 240c is ≧5, while the trench depth is ≧10 μm. The doped polysilicon filler 242 is essentially polysilicon void-free (see FIG. 3B described below). As noted above, “essentially void-free” as used herein refers at least 90% of a plurality of dielectric lined polysilicon filled trenches on an IC being void-free through their volume determinable from cross-section images obtained using X-SEM, where the dielectric lined polysilicon filled trenches 240a, 240b and 240c have a depth of ≧10 μm and an AR≧5. The difference in dopant concentration from the top the polysilicon filled trench and the bottom of the polysilicon filled trench is at least a factor of 4, and an average polysilicon grain size at the top of the polysilicon filled trench is at least 50% less than an average grain size at the bottom of the polysilicon filled trench.

FIG. 2B is a schematic cross-sectional view of an example IC 250 including disclosed polysilicon filled trenches 240a′ and 240c′ each having an opening 243 at a bottom of the dielectric liner 241 that is otherwise conformal to provide an ohmic contact between the doped polysilicon filler 242 in the trench and the semiconductor substrate 205, according to an example embodiment. Contact metal 245 is shown contacting the doped polysilicon filler 242 in polysilicon filled trenches 240a′ and 240c′. In this embodiment, the doped polysilicon filler 242 is boron doped to provide an ohmic contact to the semiconductor substrate as it is shown to also be p- (boron) doped.

Disclosed methods have several significant advantages compared to known polysilicon trench fill doping methods besides providing essentially void-free polysilicon. Such other advantage include low polysilicon sheet resistance in the trench, typically ≦30 oms/sq for a boron doped trench, improved wafer-to-wafer and across the wafer sheet resistance (Rs) uniformity including for up to and including 300 mm wafers, with the ability to obtain these results with a 1× wafer spacing (e.g. ˜7.8 mm spacing) for wafers on the boat in the deposition (e.g., LPCVD) furnace. A relatively high BCl₃ flow rate (e.g., ≧40 sccm, where a lower maximum flow rate of 10 sccm is generally used in conventional in-situ doped deposition processes), has been found to enable lower Rs and improved Rs uniformity. The thicker undoped polysilicon layer compared to the doped polysilicon layer (e.g., by a ≧4:1 ratio) also reduces or eliminates sidewall trench liner oxide loss defects.

### EXAMPLES

Disclosed embodiments are further illustrated by the following specific Examples, which should not be construed as limiting the scope or content of this Disclosure in any way.

FIG. 3A is a scanned X-SEM image of conventional polysilicon filled trenches having visible v-shaped voids doped taken after polysilicon deposition followed by a known boron ion implantation process and then an implant activation step. Trenches were formed by reactive ion etching (RIE), lined by a thermally grown silicon oxide dielectric (1.5 kA to 2.5 kA), and then a thin layer of undoped polysilicon (˜2 kA) was deposited. The wafers were then processed on an ion implant tool to obtain an angled implant into the trenches. After the implant step was completed the wafers were taken back to the furnace to obtain thicker (˜12 kA to 14 kA) undoped polysilicon to fill the trench completely. After the deposition/implant/deposition process the wafers were annealed at high temperature to activate the dopants in the trench and to enable the dopants to diffuse so that they become distributed more uniformly in the trench. For a process having a relative low DT following boron implantation of the polysilicon, as shown in FIG. 3A at least one 1 void tended to form in each trench particularly for relatively small trench widths (e.g., <3 μm) and deep trench depths (e.g., >20 μm).

FIG. 3B is a scanned X-SEM image of a test structure having disclosed polysilicon filled trenches with varying trench opening/width size that simulated product features with varying trench openings/widths that were formed using a disclosed in situ boron doped polysilicon deposition process based on method 100, where the doped polysilicon filler is seen to be essentially polysilicon void-free. Trenches were formed by RIE, lined by a thermally grown silicon oxide dielectric, and filled as described above, except instead of ion implanting the polysilicon the polysilicon was doped by a disclosed in situ boron polysilicon deposition (step 104; thickness 0.3 μm) followed by an undoped polysilicon deposition (step 105; thickness 1.6 μm). The X-SEM was taken after the respective polysilicon depositions but before CMP. The trench opening at the top semiconductor surface was varied 2.45 μm to 2.85 μm and the trench depth was kept at 28 μm.

The different trench width (opening) shown in FIG. 3B has the opening size increasing from left to right. The dielectric (silicon oxide) liner is shown as being black in color due to X-SEM contrast with the dielectric being insulating and the polysilicon filler being electrically conducting. The horizontally oriented features in the silicon between the trenches is due to sample cleave from the SEM and should be ignored. Polysilicon is on the top of the whole test structure. The inset provided shows a nominal trench opening of 2.65 μm with complete polysilicon filling with no voids shown and the bottom of the silicon oxide liner optionally selectively etched to allow the boron doped polysilicon filler to make ohmic contact to the p- substrate.

Disclosed embodiments can be used to form semiconductor die that may be integrated into a variety of assembly flows to form a variety of different devices and related products. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, Insulated Gate Bipolar Transistor (IGBT), CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

1. A method of fabricating an integrated circuit (IC), comprising:
etching a trench in a semiconductor layer on a substrate having an aspect ratio (AR)≧5 and a trench depth≧10 μm;
forming a dielectric liner along walls of said trench to form a dielectric lined trench, and
depositing an initial in-situ doped polysilicon layer having a first thickness into said trench to form a dielectric lined partially polysilicon filled trench;
depositing an un-doped polysilicon layer having a second thickness greater than said first thickness on said initial in-situ doped polysilicon layer to complete a filling of said dielectric lined trench to provide a polysilicon filled trench;
wherein after completion of said fabricating of the IC said polysilicon filled trench is essentially polysilicon void-free, and has a 25° C. sheet resistance less than or equal≦60 ohms/sq.

2. The method of claim 1, wherein a thickness of said initial in-situ doped polysilicon layer is from 0.2 μm to 0.5 μm, and a thickness of said un-doped polysilicon layer is from 1.3 μm to 2.0 μm.

3. The method of claim 1, wherein after said completion of said fabricating of said IC a difference in a concentration of dopant from a top of said polysilicon filled trench and a bottom of said polysilicon filled trench is at least a factor of 4, and wherein an average grain size at said top of said polysilicon filled trench is at least 50% less than an average grain size at said bottom of said polysilicon filled trench.

4. The method of claim 1, wherein said initial in-situ doped polysilicon layer as deposited has an average dopant concentration between 5×10¹⁸ cm⁻³ and 1×10²¹ cm⁻³.

5. The method of claim 1, wherein said substrate is a bulk substrate material that provides said semiconductor layer.

6. The method of claim 1, wherein said trench depth is between 20 μm and 50 μm.

7. The method of claim 1, wherein said semiconductor substrate is boron doped, further comprising etching an opening at a bottom of said dielectric liner before said depositing said initial in-situ doped polysilicon layer doped with boron to provide an opening for an ohmic contact to said semiconductor substrate.

8. The method of claim 1, wherein said depositing said initial in-situ doped polysilicon layer comprises boron doping including flowing BCl₃ gas in a flow range from 20 to 50 Standard Cubic Centimeters per Minute (sccm) along with at least one diluent gas so that said BCl₃ gas is diluted to less than or equal to (≦) 20% by Gravimetric volume mixture.

9. The method of claim 8, wherein said diluent gas comprises H₂.

10. The method of claim 8, wherein said depositing said initial in-situ doped polysilicon layer uses a temperature range of 550° C. to 650° C. and a pressure range from 100 mTorr to 400 mTorr.

11. The method of claim 1, further comprising annealing said polysilicon filled trench at a temperature between 900° C. and 1150° C.

12. An integrated circuit (IC), comprising:
a semiconductor layer on a substrate;
functional circuitry formed on said semiconductor substrate, and
a plurality of polysilicon filled trenches having a dielectric liner in said semiconductor substrate having a doped polysilicon filler therein;
wherein a 25° C. sheet resistance of said doped polysilicon filler is ≦60 ohms/sq,
wherein an aspect ratio (AR) of said plurality of polysilicon filled trenches is ≧5 and a trench depth is ≧10 μm, and
wherein said doped polysilicon filler is essentially polysilicon void-free, wherein a difference in a concentration of a dopant from a top of said polysilicon filled trench and a bottom of said polysilicon filled trench is at least a factor of 4, and wherein an average grain size at said top of said polysilicon filled trench is at least 50% less than an average grain size at said bottom of said polysilicon filled trench.

13. The IC of claim 12, wherein an average dopant concentration in said doped polysilicon filler is between 5×10¹⁸ cm⁻³ and 5×10²¹ cm⁻³, and a 25° C. sheet resistance of said doped polysilicon filler is ≦50 ohms/sq.

14. The IC of claim 12, wherein said semiconductor substrate is a bulk substrate material that provides said semiconductor layer.

15. The IC of claim 12, wherein said trench depth is between 20 μm and 50 μm.

16. The IC of claim 12, further comprising openings in said dielectric liner at a bottom of said polysilicon filled trench, wherein said doped polysilicon filler provides an ohmic contact to said semiconductor layer.

17. The IC of claim 16, wherein said semiconductor layer is boron doped, said doped polysilicon filler is boron doped, and wherein said 25° C. sheet resistance of said doped polysilicon filler is ≦30 ohms/sq.

18. An integrated circuit (IC), comprising:
a boron doped semiconductor layer on a substrate;
functional circuitry formed on said semiconductor layer, and
a plurality of polysilicon filled trenches having a dielectric liner in said semiconductor layer having a boron doped polysilicon filler therein,
wherein a 25° C. sheet resistance of said doped polysilicon filler is ≦50 ohms/sq,
wherein an aspect ratio (AR) of said plurality of polysilicon filled trenches is ≧5 and a trench depth is between 20 μm and 50 μm, wherein a difference in boron concentration from a top of said polysilicon filled trench and a bottom of said polysilicon filled trench is at least a factor of 4, and wherein an average grain size at said top of said polysilicon filled trench is at least 50% less than an average grain size at said bottom of said polysilicon filled trench, and
wherein said doped polysilicon filler is essentially polysilicon void-free.

19. The IC of claim 18, wherein said 25° C. sheet resistance of said doped polysilicon filler is ≦30 ohms/sq.

20. The IC of claim 18, further comprising openings in said dielectric liner at a bottom of said polysilicon filled trench, wherein said doped polysilicon filler provides an ohmic contact to said semiconductor layer.
